(19) United States
(12) Patent Application Publication
(10) Pub. No.: US 2016/0027998 A1
(43) Pub. Date: Jan. 28, 2016

(54) VIA FORMED UNDERLYING A MANGETORESISTIVE DEVICE AND METHOD OF MANUFACTURE

(71) Applicant: Everspin Technologies, Inc., Chandler, AZ (US)

(72) Inventors: Chaitanya Mudivarthi, Chandler, AZ (US); Sanjeev Aggarwal, Scottsdale, AZ (US)

(21) Appl. No.: 14/340,209

(22) Filed: Jul. 24, 2014

(51) Int. Cl. H01L 43/12; H01L 43/08; H01L 43/02

(52) U.S. Cl. CPC H01L 43/12; H01L 43/02; H01L 43/08

(57) ABSTRACT

A via underlying a magnetoresistive device is formed to include a lower portion that includes a first material and an upper portion that includes a second material, where the second material is part of the material making up the bottom electrode of the magnetoresistive device. The via is formed by partially filling a via hole with the first material and then filling the remaining portion of the via hole when a layer of the second material is deposited to form the basis for the bottom electrode. The layer of second material is polished to provide a planar surface on which to form the magnetoresistive stack and top electrode. After forming the magnetoresistive stack and top electrode, the layer of second material is etched to form the bottom electrode. Such a via allows the magnetoresistive stack to be formed directly over the via, thereby reducing the area required for each device and increasing density in applications such as MRAMs.

### TECHNICAL FIELD

The disclosure herein relates generally to magnetoresistive devices and associated interconnect. More particularly, this disclosure relates to vias underlying magnetoresistive devices and the manufacture of such circuit elements.

### BACKGROUND

Magnetoresistive memory devices store information by varying the resistance across the memory device such that a read current through a memory cell in the memory device will result in a voltage drop having a magnitude that is based on the information stored in the memory cell. For example, in certain magnetic memory devices, the voltage drop across a magnetic tunnel junction (MTJ) can be varied based on the relative magnetic states of the magnetic layers within the memory cell. In such memory devices, there is typically a portion of the memory cell that has a fixed magnetic state and another portion that has a free magnetic state that is controlled to be either parallel or antiparallel to the fixed magnetic state. Because the resistance through the memory cell changes based on whether the free portion is parallel or antiparallel to the fixed portion, information can be stored by setting the orientation of the free portion. The information is later retrieved by sensing the orientation of the free portion. Such magnetic memory devices are well known in the art.

Writing to magnetic memory cells can be accomplished by sending a spin-polarized write current through the memory device where the angular momentum carried by the spin-polarized current can change the magnetic state of the free portion. One of ordinary skill in the art understands that such a current can either be directly driven through the memory cell or can be the result of applying one or more voltages, where the applied voltages result in the desired current. Depending on the direction of the current through the memory cell, the resulting magnetization of the free portion will either be parallel or antiparallel to the fixed portion. If the parallel orientation represents a logic “0”, the antiparallel orientation may represent a logic “1”, or vice versa. Thus, the direction of write current flow through the memory cell determines whether the memory cell is written to a first state or a second state. Such memory devices are often referred to as spin torque transfer memory devices. In such memories, the magnitude of the write current is typically greater than the magnitude of a read current used to sense the information stored in the memory cells.

In an array of magnetoresistive memory cells, each memory cell is often coupled to a corresponding selection transistor that allows each memory cell to be individually selected for access. The selection transistor for each memory cell couples to one of the electrodes on either side of the magnetoresistive stack of the memory cell. The selection transistors are often formed underlying the layers in which the memory cells are formed, thereby requiring a via that extends through an interlayer dielectric to establish the electrical connection between each memory cell and its corresponding selection transistor.

Because an MRAM may include thousands or millions of memory cells, reducing the amount of area needed for each memory cell and the associated access circuitry for the memory cell can provide for increased memory cell density. Higher memory cell density allows for greater data storage capacity for the MRAM. Therefore, it is desirable to provide techniques for manufacturing such devices that support increased densities while still ensuring proper device operation and reliability.

### BRIEF DESCRIPTION OF THE DRAWINGS

FIG. 1 illustrates a cross-sectional view of a magnetoresistive device and corresponding via in an offset position;

FIGS. 2-11 illustrate cross-sectional views of layers included in a magnetoresistive device and a corresponding via during different stages of the manufacturing in accordance with exemplary embodiments; and

FIG. 12 is a flow chart of a method of manufacturing a magnetoresistive device in accordance with an exemplary embodiment.

### DETAILED DESCRIPTION

The following detailed description is merely illustrative in nature and is not intended to limit the embodiments of the subject matter or the application and uses of such embodiments. Any implementation described herein as exemplary is not necessarily to be construed as preferred or advantageous over other implementations.

For simplicity and clarity of illustration, the figures depict the general structure and/or manner of construction of the various embodiments. Descriptions and details of well-known features and techniques may be omitted to avoid unnecessarily obscuring other features. Elements in the figures are not necessarily drawn to scale: the dimensions of some features may be exaggerated relative to other elements to assist improve understanding of the example embodiments. For example, one of ordinary skill in the art appreciates that the cross-sectional views are not drawn to scale and should not be viewed as representing proportional relationships between different layers. The cross-sectional views are provided to help illustrate the processing steps performed by simplifying the various layers to show their relative positioning. Moreover, while certain layers and features are illustrated with straight 90-degree edges, in actuality or practice such layers may be more “rounded” and gradually sloping.

The terms “comprise,” “include,” “have” and any variations thereof are used synonymously to denote non-exclusive inclusion. The term “exemplary” is used in the sense of “example,” rather than “ideal.”

During the course of this description, like numbers may be used to identify like elements according to the different figures that illustrate the various exemplary embodiments.

For the sake of brevity, conventional techniques related to semiconductor processing may not be described in detail herein. The exemplary embodiments may be fabricated using known lithographic processes. The fabrication of integrated circuits, microelectronic devices, micro electro mechanical devices, microfluidic devices, and photonic devices involves the creation of several layers of materials that interact in some fashion. One or more of these layers may be patterned so various regions of the layer have different electrical or other characteristics, which may be interconnected within the layer or to other layers to create electrical components and circuits. These regions may be created by selectively introducing or removing various materials. The patterns that define such regions are often created by lithographic processes. For example, a layer of photoresist is applied onto a layer overlying a wafer substrate. A photo mask (containing clear and opaque areas) is used to selectively expose the photoresist by a form of radiation, such as ultraviolet light, electrons, or x-rays. Either the photoresist exposed to the radiation, or that not exposed to the radiation, is removed by the application of a developer. An etch may then be applied to the underlying layer not protected by the remaining resist such that the layer overlying the substrate is patterned. Alternatively, an additive process can be used in which a structure is built up using the photoresist as a template.

There are many inventions described and illustrated herein, as well as many aspects and embodiments of those inventions. In one aspect, the described embodiments relate to, among other things, methods of manufacturing a magnetoresistive-based device having one or more electrically conductive electrodes or conductors on either side of a magnetoresistive stack. As described in further detail below, the magnetoresistive stack may include many different layers of material, where some of the layers include magnetic materials, whereas others do not. In some embodiments, the methods of manufacturing include forming the layers for the magnetoresistive device and then masking and etching those layers to produce a magnetic tunnel junction (MTJ) device. Examples of MTJ devices include transducers such as electromagnetic sensors as well as memory cells.

Magnetoresistive devices are typically formed to include a top electrode and a bottom electrode that permit access to the device by allowing for connectivity to other circuit elements. In the example of a magnetic memory (MRAM) cell, one of the electrodes may be coupled to a bit line, whereas the other is coupled to a sense line. A selection transistor may be included between one of the electrodes and the bit or sense line to allow for selection/de-selection of the particular memory cell. The coupling to the electrodes may be accomplished using vias, which are interlayer holes within interlayer dielectric material of the device structure that are filled with conductive material, thereby allowing electrical current to pass between the layers joined by the via.

Within the magnetoresistive device, a set of layers is included between the electrodes, where the set of layers may be referred to as the “magnetoresistive stack.” In a magnetoresistive device that includes a magnetic tunnel junction (MTJ), the magnetoresistive stack includes a fixed layer and a free layer on either side of a dielectric layer that forms a tunnel junction. In some embodiments, the fixed layer achieves its fixed magnetization based on interaction with an antiferromagnetic material. In other embodiments, the fixed magnetization may be achieved through other means, including the manner in which the fixed layer was formed, shape anisotropy, etc. In manufacturing such magnetoresistive devices, a set of layers is first deposited on the wafer and then patterned and etched in multiple steps to define the electrodes, the various layers in the magnetoresistive stack, and any underlying and overlying connections and circuits.

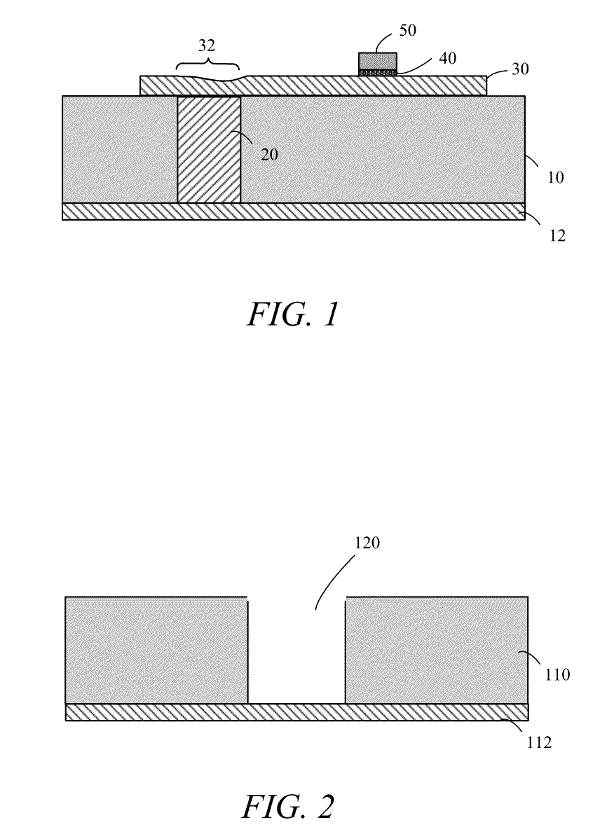

FIG. 1 illustrates a cross-sectional view of a magnetoresistive device that includes a top electrode 50, a magnetoresistive stack 40, and a bottom electrode 30. The magnetoresistive device is positioned over an interlayer dielectric layer 10. A via 20 provides an electrical connection between the bottom electrode 30 and an underlying interconnect metal layer 12, thereby enabling additional circuits (e.g. a selection transistor) to electrically couple to the magnetoresistive device using the via 20. As shown in FIG. 1, the via 20 is offset from the stack 40 and top electrode 50 such that the via 20 is not in vertical alignment with the stack 40 and top electrode 50. Conventionally, the via 20 is filled with a conductive material such as copper. The bottom electrode 30 is formed by depositing a layer of conductive material over the already formed copper via 20 and then etching through portions of the layer of conductive material. Variations in the layer corresponding to the bottom electrode, shown as aberrations 32, may render the surface of the bottom electrode directly above the via 20 unsuitable as a base for formation of the stack 40 and the top electrode 50. As such, in order to provide a good base for formation of the stack 40 and top electrode 50, those structures are offset with respect to the position of the via 20. In addition, copper filled vias are prone to corrosion from the etching chemistries used to form the magnetoresistive stack 40 and top electrode 50. As such, having the bottom electrode 30 completely cover the underlying copper via 20 can protect the copper via 20 during those etching operations.

As can be seen from FIG. 1, the area required to support the magnetoresistive device and associated via is increased by having to offset the stack 40 and top electrode 50 from the via 20. In instances where an array of magnetoresistive devices are closely spaced together, the extra area required to offset the stack 40 from the via 20 leads to lower device densities because of the larger per-device area requirements. In applications such as MRAMs, the lower density limits the amount of data that can be stored on a single MRAM.

As disclosed herein, by only partially filling the via underlying the bottom electrode with conductive material such as copper and then filling the remaining portion with the material used to form the bottom electrode, problems associated with positioning the via directly under the magnetoresistive stack are avoided, thereby enabling placement of the via in vertical alignment with the stack and top electrode. By positioning the stack directly over the via, area requirements are reduced, thereby allowing for increased densities in applications such as MRAMs.

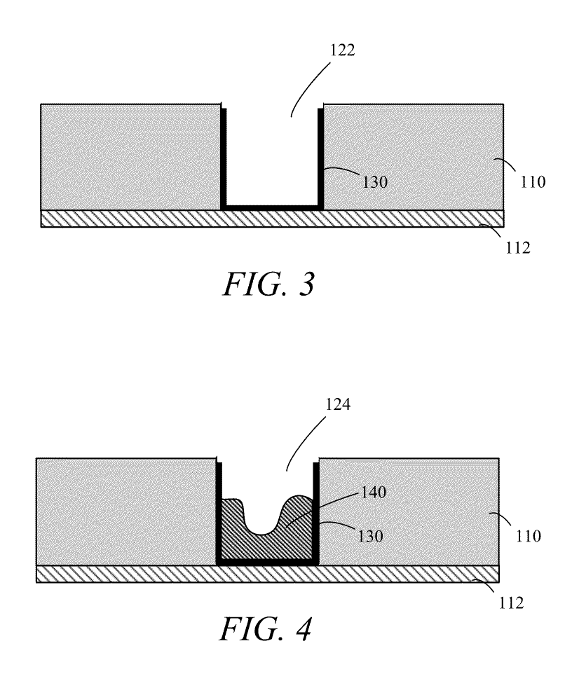

FIG. 2 illustrates a cross-sectional view of an interlayer dielectric 110 in which a hole 120 has been formed. The hole 120, which is eventually filled with conductive material to produce a via, may be formed by selective etching that removes a portion of the interlayer dielectric material 110. The hole 120 provides access to the underlying interconnect metal layer 112, which facilitates connections to other circuit elements. After forming the hole 120 for the via, a barrier layer may be formed within the hole, resulting in a barrier-lined hole 122 shown in FIG. 3. Forming the barrier layer within the hole may include forming a barrier layer over the entire wafer on which the hole is formed and then removing the portions of the layer outside of the whole using polishing or etching. The barrier layer 130 lines at least the upper portion of the inner walls the hole 122. In some embodiments, the barrier layer 130 coats the entirety of the inner walls of the hole 122. The barrier layer 130 prevents unwanted diffusion of the later-deposited conductive material that partially fills the hole 120. For example, if the conductive material deposited to partially fill the via is copper or ruthenium, then the barrier layer 130 typically includes tantalum (Ta) and/or tantalum nitride (TaN). In one embodiment, the conductive material used to fill the rest of the via and form the bottom electrode for the magnetoresistive device is tantalum or tantalum nitride, whereas in other embodiments, any bottom electrode material, now known or later developed, can be used to fill the rest of the via hole. The material included in the barrier layer 130 can be selected to correspond to the material included in the via such that the barrier layer 130 is effective in preventing unwanted diffusion or other interaction by the material(s) included in the via with the surrounding material.

In addition to the barrier layer 130, a seed layer may also be formed within the hole 122. The seed layer includes seed material corresponding to the electrically conductive material that is used to partially fill the via hole 122. For example, if the lower portion of the via hole 122 is to be filled with copper, a seed layer of copper may be deposited after or with the barrier layer 130. The seed layer is intended to facilitate better deposition/plating of the conductive material within the via hole 122. In some embodiments a seed layer may not be required, and the via can be filled using electroless plating of material such as ruthenium.

As shown in FIG. 4, conductive material 140 is deposited within the via hole 122, thereby leaving an unfilled via hole portion 124. The conductive material may include conductive materials such as copper, ruthenium, tungsten, or combinations thereof. In some process flows, filling vias is accomplished using a copper plating technique that includes three steps. Those steps include hot entry, trench fill, and overburden. By controlling the trench fill and/or overburden steps, the via hole may be left only partially filled, thereby providing the desired level of copper within the via hole in accordance with embodiments described herein.

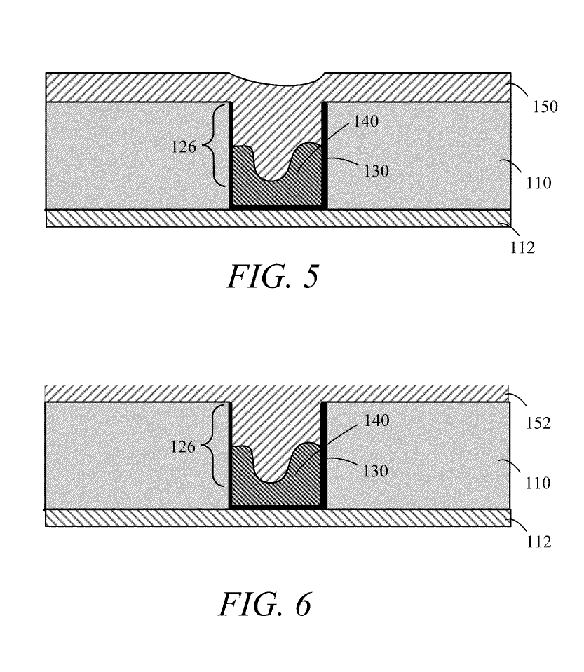

FIG. 5 illustrates a cross-sectional view corresponding to the structure from FIG. 4 following deposition of a lower layer of conductive material 150 corresponding to the bottom electrode for the magnetoresistive device. The material included in the lower layer of conductive material 150 is preferably selected to provide a good base for formation of the plurality of layers corresponding to the magnetoresistive stack that a subsequently formed over the lower layer of conductive material 150. For example, tantalum or tantalum nitride provide the desired characteristics for such a base. Other examples include ruthenium, titanium, titanium nitride, and tungsten. As shown, the lower layer of conductive material 150 extends down into the via hole, filling the remaining portion of the hole not already filled with copper. Thus, the filled via 126 may include a barrier layer, a seed layer, a partial fill of conductive material 140, and further conductive material corresponding to the bottom electrode layer 150. In some embodiments, deposition of the lower layer of conductive material 150 is accomplished using chemical vapor deposition (CVD) or electroplating, both of which allow the material to be deposited in a uniform manner such that keyholes or other unintentional unfilled areas or gaps do not result within the layer 150. In other embodiments, deposition of the lower layer of conductive material 150 is accomplished using physical vapor deposition (PVD).

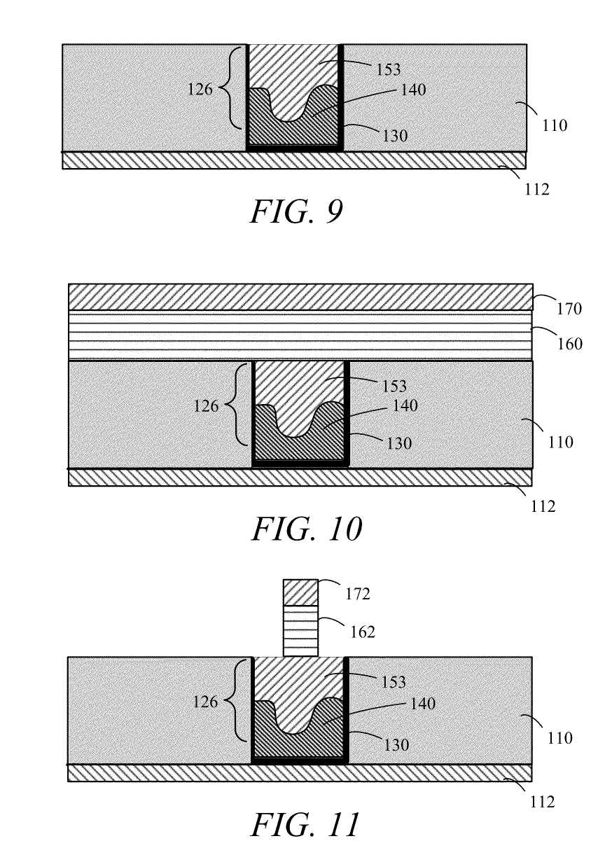

As shown in FIG. 6, following deposition of the lower layer of conductive material 150, the top surface of the lower layer of conductive material 150 is leveled to form a layer 152 with a generally planar upper surface. Leveling may be accomplished by performing a polishing step such as chemical mechanical polishing, where such polishing steps are well known in the art. While FIG. 6 shows the remaining portion of the layer 152 overlying the interlayer dielectric outside of the hole for the via 126, in other embodiments, the polishing may eliminate the portions of the layer of conductive material 152 outside of the via 126. In other words, in FIG. 6, the polishing has not polished all the way down to the top of the via 126, whereas in other embodiments, the polishing may remove all aspects of the layer 152 except those included within the via 126. In such alternate embodiments, the thickness of the conductive layer 152 outside of the via 126 would be reduced to zero. FIGS. 9-11, described in more detail below, reflect such an example embodiment.

In some embodiments, the conductive layer 152 may be made up of a plurality of layers. For example, a first material may form a lower portion of conductive layer 152, while a second material overlying the first material forms an upper portion of the bottom electrode.

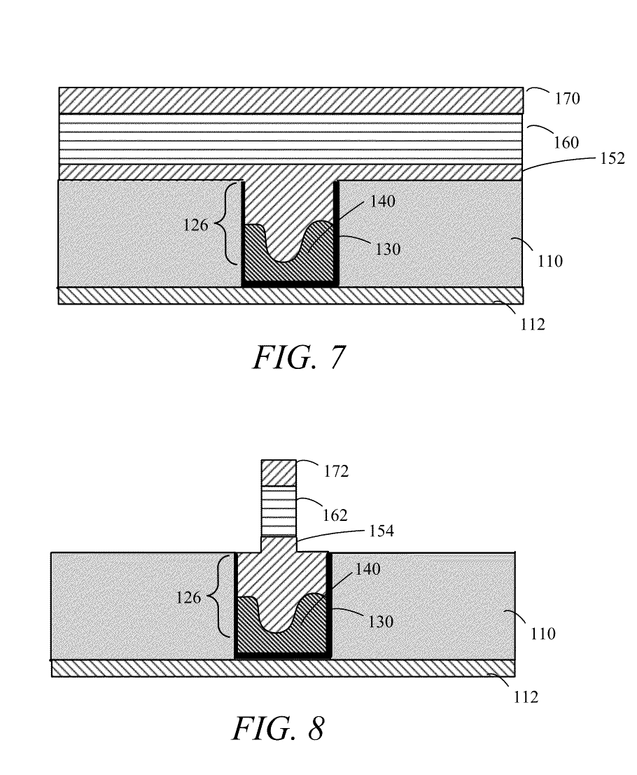

As shown in FIG. 7, once the layer of conductive material 152 has been planarized to provide a generally planar upper surface, the plurality of layers corresponding to the magnetoresistive device stack 160 are deposited overlying the layer 152. In some embodiments, layers formed over the conductive layer 152 may also be conductive. In other words, one or more layers included in the plurality of layers 160 may be conductive and may be adjacent to the conductive layer 152. In such embodiments, all of those layers may be considered to be a part of the bottom electrode of the magnetoresistive device.

The magnetoresistive stack may include a number of different layers of both magnetic and nonmagnetic material. For example, the layers of the stack may include multiple layers of magnetic material, dielectric layers that provide one or more tunnel barriers or diffusion barriers, coupling layers between layers of magnetic material that provide for ferromagnetic or antiferromagnetic coupling, one or more layers of anti-ferromagnetic material, as well as other layers utilized in magnetoresistive stacks as currently known or later developed. In one example, the magnetoresistive stack may include a lower layer of magnetic material, an upper layer of magnetic material, and a dielectric layer providing a tunnel barrier between the upper and lower layers of magnetic material. The lower layer of magnetic material may include a set of layers forming a synthetic antiferromagnetic structure (SAF), and the upper layer of magnetic material may include a set of layers corresponding to a synthetic ferromagnetic structure (SYF). In another embodiment, the lower layer of magnetic material may include a SAF structure as well as a layer of antiferromagnetic material that provides a reference magnetic field for the SAF structure. Notably, each of the layers included in the magnetoresistive device may be a composite layer that includes multiple sub-layers. In other embodiments, the magnetoresistive stack may include multiple SAFs, SYFs, and tunnel barriers in addition to the other layers, where the materials and structures are arranged in various combinations and permutations now known or later developed.

As also shown in FIG. 7, after depositing the plurality of layers corresponding to the magnetoresistive stack 160, an upper layer of conductive material 170 is deposited over the plurality of layers corresponding to the magnetoresistive stack 160. The upper layer of conductive material 170 forms the basis for the top electrode of the device, and can include any suitable material now known or later developed for such a purpose, including the materials listed above as suitable for the bottom electrode 152. In some embodiments, the upper layer of conductive material may include a plurality of layers of conductive material.

FIG. 8 illustrates a cross-sectional view of the magnetoresistive device as formed over the via 126. Following deposition of the layers as shown in FIG. 7, selective etching is used to remove portions of each of the layers 152, 160, and 170, where the result is a bottom electrode 154, a magnetoresistive stack 162, and a top electrode 172, respectively. The bottom electrode 154 is not etched until after the layers corresponding to the magnetoresistive stack 162 and top electrode 172 have already been etched. As shown in FIG. 8, the magnetoresistive device is positioned directly above the via 126. Notably, the top portion of the via 126 is filled with material corresponding to the bottom electrode 154. As noted above, copper, which may be included in the bottom part of the via 126, may be susceptible to the etching chemistries used to form the magnetoresistive device shown in FIG. 8. However, materials such as tantalum, tantalum nitride, or other suitable bottom electrode materials are not as susceptible to degradation from those etching chemistries. As such, the material included in the upper portion of the via 126 protects the lower copper portion 140 from degradation during etching.

As illustrated in FIG. 8, the dimensional footprint of the via 126 within the interlayer dielectric 110 may be greater than the dimensional footprint corresponding to the magnetoresistive device. As such, the magnetoresistive device may be formed such that the footprint of the magnetoresistive device lies completely within the footprint of the via 126. In such an embodiment, the critical dimension for the magnetoresistive device in terms of area corresponds to the footprint of the via 126 as opposed to the much larger area required in the example illustrated in FIG. 1 where the via is offset from the magnetoresistive stack. By forming the magnetoresistive device directly above the via 126, area requirements are reduced, thereby enabling increased density in applications such as MRAMs, which include a large number of MTJ memory cells in an array. In other embodiments, the dimensional footprint of the via 126 may be smaller than that of the overlying magnetoresistive device. In such other embodiments, the magnetoresistive device may be formed such that the footprint of the via 126 lies completely within the footprint of the magnetoresistive device. As such, the magnetoresistive device and via 126 need not be offset as shown in FIG. 1, but instead can be vertically positioned such that the area needed corresponds to the larger of the via and the magnetoresistive device.

As noted above, FIGS. 9-11 present cross-sectional views of device formation in accordance with an alternate embodiment in which the entirety of the bottom electrode is included within the via underlying the device. FIG. 9 illustrates a cross-sectional view corresponding to FIG. 6 following polishing to remove all of the lower layer of conductive material 150 except the material 153 within the via 126. Thus, the lower layer of conductive material corresponding to the bottom electrode is limited to an area within the via hole. FIG. 10 corresponds to the cross-sectional view of FIG. 9 following deposition of the plurality of layers 160 corresponding to the magnetoresistive stack as well as the upper layer of conductive material 170 corresponding to the top electrode. In FIG. 11, the magnetoresistive device is fully formed, where the bottom electrode for the magnetoresistive device is fully included in the underlying via 126.

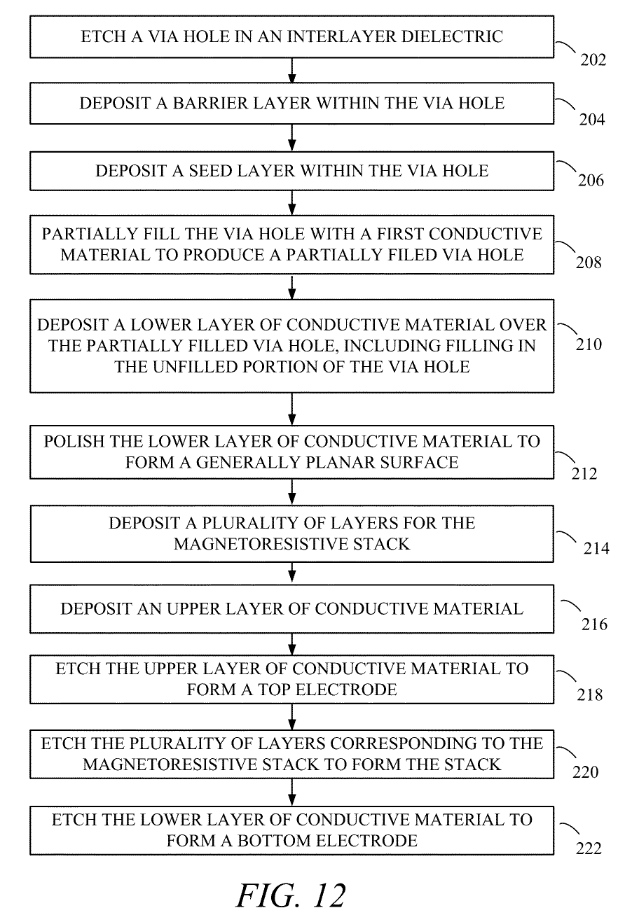

FIG. 12 is a flow chart that illustrates exemplary embodiments of a method of manufacturing a magnetoresistive device, where, in one example, the magnetoresistive device is a spin-torque MTJ device included in an MRAM. The operations included in the flow chart may represent only a portion of the overall process used to manufacture the device. The various tasks performed in connection with the methods of FIG. 12 may be performed by software, hardware, firmware, or any combination thereof For illustrative purposes, the following description of the method in FIG. 12 may refer to elements mentioned above in connection with FIGS. 2-11. In practice, portions of methods may be performed by different elements of the described system, e.g., a processor, a display element, or a data communication component. It should be appreciated that methods may include any number of additional or alternative tasks, the tasks shown in FIG. 12 need not be performed in the illustrated order, and the methods may be incorporated into a more comprehensive procedure or process having additional functionality not described in detail herein. Moreover, one or more of the tasks shown in FIG. 12 could be omitted from an embodiment as long as the intended overall functionality remains intact.

FIG. 12 illustrates a flow chart of a portion of the magnetoresistive device manufacturing process and corresponding via formation, where the via is formed such that it lies under the magnetoresistive stack for the magnetoresistive device. At 202, a hole is etched in a layer of material corresponding to an interlayer dielectric. The hole provides an opening within the interlayer dielectric at a location corresponding to a via used to provide a specific electrical connection.

At 204, a barrier layer is deposited in the hole formed at 202. The barrier layer is intended to prevent diffusion of later deposited materials. For example, a barrier layer or tantalum and/or tantalum nitride may be used to prevent diffusion of later-deposited copper used to partially fill the via, where diffusion of the copper into the surrounding materials may negatively impact device operation. As such, the barrier layer material may be selected based on the material first used to partially fill the via such that it serves a proper barrier to that material.

At 206 a seed layer is deposited over the barrier layer within the whole. The seed layer serves to facilitate subsequent deposition/plating of the conductive material that partially fills the via hole. For example, if copper is used to fill the lower portion of the via hole, a copper seed layer is deposited at 206. In some embodiments, the seed layer and barrier layer may be deposited together in a single step. In other embodiments, only the seed layer or only the barrier layer may be deposited.

At 208, the whole is partially filled with a first conductive material to form a partially filled via hole. The material selected to partially fill the hole may be a metal such as copper, ruthenium, tungsten, or various combinations or alloys thereof After partially filling the via hole at 208, a lower layer of conductive material is deposited at 210. The lower layer of conductive material fills in the remaining unfilled portion of the partially filled via hole. Deposition of the lower layer of conductive material can include chemical vapor deposition such that a good level of material uniformity is achieved. Materials included in the lower layer of conductive material can include one or more of tantalum, tantalum nitride, ruthenium, titanium, titanium nitride, and tungsten. The lower layer of conductive material may include alloys or composite layers where multiple materials are included. For example, the lower layer of electrically conductive material can include a layer of tantalum over a layer of tantalum nitride.

At 212, the lower layer of conductive material is polished to produce a generally planar upper surface of the lower layer of conductive material. The polishing may be done using chemical mechanical polishing. As noted above, a planar upper surface of the lower layer of conductive material provides a good base upon which to form subsequent layers corresponding to the magnetoresistive device. As also noted above, the polishing performed at 212 may include removal of all of the lower layer of conductive material outside of the via hole. In such embodiments, the generally planar upper surface of the lower layer of conductive material corresponds to an upper surface of the interlayer dielectric. An example of such an embodiment is shown in FIG. 9. In other embodiments, additional material that extends above and outside the via hole may remain after the polishing step. In those embodiments, the generally planar upper surface of the lower layer of conductive material extends above an upper surface of the interlayer dielectric. An example of such an embodiment is shown in FIG. 6.

At 214, a plurality of layers corresponding to the magnetoresistive stack are deposited over the lower layer of conductive material. At 216 an upper layer of conductive material is deposited over the plurality of layers corresponding to the magnetoresistive stack. At 218, the upper layer of conductive material is etched to form a top electrode. At 220, the plurality of layers corresponding to the magnetoresistive stack are etched to form the magnetoresistive stack. In some embodiments, the top electrode and magnetoresistive stack are patterned and defined through etching such that they lie directly over the via. By positioning the magnetoresistive stack directly above the via, the area required to support the magnetoresistive device and corresponding via is reduced in comparison to that required when the magnetoresistive stack is offset from the via as depicted and described with respect to FIG. 1. In some embodiments, the via has a dimensional footprint within the interlayer dielectric that is larger than a second dimensional footprint corresponding to the magnetoresistive stack and top electrode. In other words, the via may be much larger in length and width than the magnetoresistive stack and top electrode. In such embodiments, the footprint corresponding to the stack and top electrode may lie completely within the footprint corresponding to the via.

At 222, after the top electrode and magnetoresistive stack have been defined by etching, the lower layer of electrically conductive material is etched to form the bottom electrode. As noted above, depending on how much of the lower layer of conductive material is left behind during polishing at 212, the entirety of the bottom electrode may be included within the via, or, in other embodiments, some aspect of the bottom electrode may extend above the via. Including a portion of the bottom electrode within the via, the underlying material (e.g. copper) is protected during etching operations corresponding to formation of the magnetoresistive device. Additional advantages in terms of area reduction are realized by positioning the magnetoresistive device directly over the via.

Although the described exemplary embodiments disclosed herein are directed to various magnetoresistive-based devices and methods for making same, the present disclosure is not necessarily limited to the exemplary embodiments, which illustrate inventive aspects that are applicable to a wide variety of semiconductor processes and/or devices. Thus, the particular embodiments disclosed above are illustrative only and should not be taken as limitations, as the embodiments may be modified and practiced in different but equivalent manners apparent to those skilled in the art having the benefit of the teachings herein. Accordingly, the foregoing description is not intended to limit the disclosure to the particular form set forth, but on the contrary, is intended to cover such alternatives, modifications and equivalents as may be included within the spirit and scope of the inventions as defined by the appended claims so that those skilled in the art should understand that they can make various changes, substitutions and alterations without departing from the spirit and scope of the inventions in their broadest form.

1. A method of manufacturing a magnetoresistive device and a via corresponding to the magnetoresistive device, comprising:
etching a via hole in an interlayer dielectric;
partially filling the via hole with a first conductive material to produce a partially filled via hole;
forming a lower layer of conductive material corresponding to a bottom electrode over the partially filled via hole, wherein forming the lower layer of conductive material includes filling an unfilled portion of the partially filled via hole;
polishing the lower layer of conductive material to provide a generally planar upper surface of the lower layer of conductive material, wherein polishing the lower layer of conductive material includes removing portions of the lower layer of conductive material such that the generally planar upper surface of the lower layer of conductive material corresponds to an upper surface of the interlayer dielectric; and
forming a top electrode and a magnetoresistive stack over the lower layer of conductive material, wherein the magnetoresistive stack is between the top electrode and the lower layer of conductive material.

2. The method of claim 1, wherein forming the top electrode and the magnetoresistive stack further comprises:
depositing a plurality of layers corresponding to the magnetoresistive stack over the lower layer of conductive material;
depositing an upper layer of conductive material over the plurality of layers corresponding to the magnetoresistive stack;
etching the upper layer of conductive material to form the top electrode; and
etching the plurality of layers corresponding to the magnetoresistive stack to form the magnetoresistive stack.

3. The method of claim 1, further comprising:
after etching the via hole and prior to partially filling the via hole, depositing a barrier layer within the via hole.

4. The method of claim 3, wherein the first conductive material is copper, and wherein the method further comprises:
after depositing the barrier layer and prior to partially filing the via hole, depositing a copper seed layer within the via hole.

5. The method of claim 1, wherein the first conductive material is copper, and wherein the method further comprises:
after etching the via hole and prior to partially filling the via hole, depositing a copper seed layer within the via hole.

6-8. (canceled)

9. The method of claim 1, wherein forming the lower layer of conductive material includes depositing a layer of conductive material using chemical vapor deposition.

10. The method of claim 1, wherein forming the lower layer of conductive material includes depositing at least one of tantalum, tantalum nitride, ruthenium, titanium, titanium nitride, and tungsten.

11. The method of claim 1, wherein forming the top electrode and the magnetoresistive stack over the lower layer of conductive material includes forming the top electrode and the magnetoresistive stack directly over the via hole.

12. The method of claim 11, wherein the via hole has a first dimensional footprint within the interlayer dielectric, wherein the top electrode and the magnetoresistive stack have a second dimensional footprint that is less than the first dimensional footprint, and wherein forming the top electrode and the magnetoresistive stack includes forming the top electrode and the magnetoresistive stack such that the second dimensional footprint lies completely within the first dimensional footprint.

13. The method of claim 11, wherein the via hole has a first dimensional footprint within the interlayer dielectric, wherein the top electrode and the magnetoresistive stack have a second dimensional footprint that is greater than the first dimensional footprint, and wherein forming the top electrode and the magnetoresistive stack includes forming the top electrode and the magnetoresistive stack such that the first dimensional footprint lies completely within the second dimensional footprint.

14. A method of manufacturing a magnetoresistive device and a via corresponding to the magnetoresistive device, comprising:
etching a via hole in an interlayer dielectric;
depositing a barrier layer on an inner surface of the via hole;
depositing a copper seed layer over the barrier layer within the via hole;
after depositing the copper seed layer, partially filling the via hole with copper to produce a partially filled via hole;
depositing a lower layer of conductive material corresponding to a bottom electrode over the partially filled via hole, wherein depositing the lower layer of conductive material includes filling an unfilled portion of the partially filled via hole;
polishing the lower layer of conductive material to form a generally planar upper surface, wherein polishing the lower layer of conductive material further comprises chemical mechanical polishing the lower layer of conductive material until the interlayer dielectric is reached such that the lower layer of conductive material is limited to an area within the via hole; and
forming a top electrode and a magnetoresistive stack on the generally planar upper surface, wherein the magnetoresistive stack is between the top electrode and the lower layer of conductive material.

15. (canceled)

16. The method of claim 14, wherein depositing a lower layer of conductive material includes depositing at least one of tantalum, tantalum nitride, ruthenium, titanium, titanium nitride, and tungsten.

17-20. (canceled)

21. A method of manufacturing a magnetoresistive device and a via corresponding to the magnetoresistive device, comprising:
etching a via hole in an interlayer dielectric;
partially filling the via hole with a first conductive material to produce a partially filled via hole;
forming a lower layer of conductive material corresponding to a bottom electrode over the partially filled via hole, wherein forming the lower layer of conductive material includes filling an unfilled portion of the partially filled via hole;
polishing the lower layer of conductive material to provide a generally planar upper surface of the lower layer of conductive material, wherein polishing the lower layer of conductive material includes removing portions of the lower layer of conductive material such that the generally planar upper surface of the lower layer of conductive material corresponds to an upper surface of the interlayer dielectric, wherein polishing the lower layer of conductive material forms the bottom electrode for the magnetoresistive device such the bottom electrode is fully included in the via for the magnetoresistive device; and
forming a top electrode and a magnetoresistive stack over the lower layer of conductive material, wherein the magnetoresistive stack is between the top electrode and the lower layer of conductive material, wherein forming the top electrode and the magnetoresistive stack over the lower layer of conductive material includes forming the top electrode and the magnetoresistive stack directly over the via hole.

22. The method of claim 21, wherein the via hole has a first dimensional footprint within the interlayer dielectric, wherein the top electrode and the magnetoresistive stack have a second dimensional footprint that is less than the first dimensional footprint, and wherein forming the top electrode and the magnetoresistive stack includes forming the top electrode and the magnetoresistive stack such that the second dimensional footprint lies completely within the first dimensional footprint.

23. The method of claim 21, wherein the via hole has a first dimensional footprint within the interlayer dielectric, wherein the top electrode and the magnetoresistive stack have a second dimensional footprint that is greater than the first dimensional footprint, and wherein forming the top electrode and the magnetoresistive stack includes forming the top electrode and the magnetoresistive stack such that the first dimensional footprint lies completely within the second dimensional footprint.

24. The method of claim 21, further comprising:
after etching the via hole and prior to partially filling the via hole, depositing a barrier layer within the via hole.

25. The method of claim 24, wherein the first conductive material is copper, and wherein the method further comprises:
after depositing the barrier layer and prior to partially filing the via hole, depositing a copper seed layer within the via hole.

26. The method of claim 21, wherein the first conductive material is copper, and wherein the method further comprises:
after etching the via hole and prior to partially filling the via hole, depositing a copper seed layer within the via hole.

27. The method of claim 21, wherein forming the lower layer of conductive material includes depositing at least one of tantalum, tantalum nitride, ruthenium, titanium, titanium nitride, and tungsten.
